(19) United States
(12) Patent Application Publication
(10) Pub. No.: US 2016/0210775 A1
(43) Pub. Date: Jul. 21, 2016

(54) VIRTUAL SENSOR TESTBED

(71) Applicant: Ford Global Technologies, LLC, Dearborn, MI (US)

(72) Inventors: Arthur Alaniz, Sunnyvale, CA (US); Vidya Nariyambut murali, Sunnyvale, CA (US); Ashley Elizabeth Micks, Mountain View, CA (US); Harpreetsingh Banvait, Sunnyvale, CA (US); Sneha Kadetotad, Sunnyvale, CA (US)

(73) Assignee: Ford Global Technologies, LLC, Dearborn, MI (US)

(21) Appl. No.: 14/945,774

(22) Filed: Nov. 19, 2015

Related U.S. Application Data
(60) Provisional application No. 62/106,072, filed on Jan. 21, 2015.

(51) Int. Cl. G06T 15/20; G06T 15/06; G06T 19/00; G05D 1/00

(52) U.S. Cl. CPC G06T 15/20; G05D 1/0088; G06T 15/06; G06T 19/006

(57) ABSTRACT

A computing device comprising a processing circuit and a data storage medium. The computing device is programmed to receive virtual sensor data that represents data collected by a virtual sensor associated with autonomously operating a virtual vehicle in a virtual environment and process the virtual sensor data to identify a limitation of a real-world sensor.

### CROSS-REFERENCE TO RELATED APPLICATIONS

This application claims priority to U.S. Provisional Application Ser. No. 62/106,072 titled “VIRTUAL SENSOR TESTBED” and filed on Jan. 21, 2015, the contents of which are hereby incorporated by reference in their entirety. This application is related to U.S. Ser. No. ______, titled “AUTONOMOUS DRIVING REFINED IN VIRTUAL ENVIRONMENTS” filed on and U.S. Ser. No. ______, titled “VIRTUAL AUTONOMOUS RESPONSE TESTBED” filed on ______.

### BACKGROUND

Autonomous vehicles are expected to interpret certain signs along the side of the road. For example, autonomous vehicles are expected to stop at stop signs. One way for autonomous vehicles to interpret signs is to “teach” the autonomous vehicle what a particular sign looks like by collecting real world sensor data. Collecting real world sensor data includes setting up physical tests or driving around with sensors to collect relevant data. In the context of identifying road signs, collecting sensor data may include collecting thousands of pictures of different road signs. There are more than 500 federally approved traffic signs according to the Manual on Uniform Traffic Control Devices.

### BRIEF DESCRIPTION OF THE DRAWINGS

FIG. 1 illustrates an example autonomous vehicle having a system programmed to receive and process virtual sensor data.

FIG. 2 is a block diagram of example components of the autonomous vehicle.

FIG. 3A illustrates an example view of a virtual environment programmed to generate virtual sensor data.

FIG. 3B illustrates another example view of a virtual environment programmed to generate virtual sensor data.

FIG. 4 is a process flow diagram of an example process that may be implemented to test and/or train one or more virtual vehicle subsystems in a virtual environment.

### DETAILED DESCRIPTION

A virtual environment is disclosed as an alternative to real-world testing. The disclosed virtual environment may include a virtual test bed for autonomous driving processes. Sensor models and image processing software may interface with virtual environments and dynamic, interactive driving scenarios. Virtual tests may provide diverse and thorough validation for driving processes to supplement and prepare for testing with real vehicles. Compared to real-world tests, virtual tests may be cheaper in terms of time, money, and resources. There may be minimal risk associated with simulating driving scenarios that would be dangerous or difficult to simulate in real-world tests, making it easier to test a wide range and a large number of scenarios, and to do so early in process of developing autonomous controls. The tool may be used during the development of sensor fusion processes for autonomous driving by integrating cameras with lidar, radar, and ultrasonic sensors, and determining the vehicle response to the interpreted sensor data.

The processes may take in sensor data and identify key elements of the virtual vehicle's surroundings needed to be designed and refined using the sample data. For example, classifiers that identify road signs may need to be trained using images of these signs, including a large and diverse set of images in order to avoid dataset bias and promote proper detection under a range of conditions. In the virtual environment, thousands of simulated camera images can be produced in seconds, making this approach an effective method of minimizing bias and optimizing classifier performance. It would also be possible to generate a database to represent all the traffic signs in the US.

A cascade classifier, which may be found in the OpenCV C++ library, may be used to identify a variety of road signs. Images of these signs may be generated in the virtual environment with randomized orientation, distance from the camera, shadow and lighting conditions, and partial occlusion. A machine learning process may take in these images as input along with the position and bounding box of the road signs in them, generate features using image processing techniques and train classifiers to recognize each sign type. Similar processes may be implemented to develop detection and recognition processes for other sensor types.

The elements shown may take many different forms and include multiple and/or alternate components and facilities. The example components illustrated are not intended to be limiting. Indeed, additional or alternative components and/or implementations may be used.

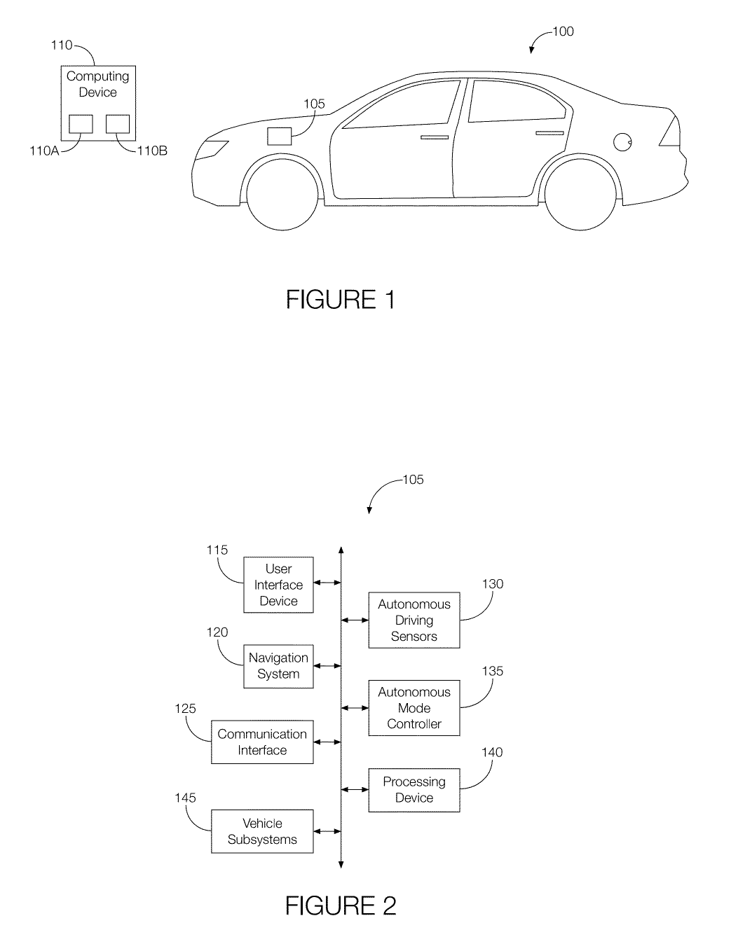

As illustrated in FIG. 1, the autonomous vehicle 100 includes a vehicle system 105 programmed to receive virtual sensor data generated in a virtual environment by a computing device 110. The computing device 110 may be programmed to simulate the virtual environment. The virtual environment may present multiple driving scenarios. Each driving scenario may include a road with various objects in the road or along the side of the road. For example, the driving scenario may include other vehicles, moving or parked, street signs, trees, shrubs, buildings, pedestrians, or the like. The different driving scenarios may further include different weather conditions such as rain, snow, fog, etc. Moreover, the driving scenarios may define different types of roads or terrain. Examples may include freeways, surface streets, mountain roads, or the like.

The computing device 110, which may include a data storage medium 110A and a processing circuit 110B, may be programmed to simulate a virtual vehicle travelling through the virtual environment. The simulation may include virtual sensors collecting virtual sensor data based on the conditions presented in the virtual environment. The computing device 110 may be programmed to collect the virtual sensor data as it would be collected on a real vehicle. For instance, the computing device 110 may simulate the virtual sensor having a view of the virtual environment as if the virtual sensor were on a real vehicle. Thus, the virtual sensor data may reflect real-world conditions relative to detecting, e.g., signs. In real world conditions, a vehicle sensor's view of a sign may be partially or completely blocked by an object such as another vehicle or a tree, for example. By simulating the virtual sensors to have the view as if it were on a real vehicle, the virtual sensor can collect virtual data according to the view that the sensor would have in real world conditions.

The output of the computing device 110 may include virtual sensor data that may be used for testing purposes, training purposes, or both, and may represent the sensor data collected by virtual sensors as a result of virtually navigating a virtual vehicle through the virtual environment. The virtual sensor data may ultimately be used to generate calibration data that can be uploaded to the vehicle system 105 so that one or more subsystems of the autonomous vehicle 100 (a real-world vehicle) may be calibrated according to the virtual sensor data collected during the testing or training that occurs when navigating the virtual vehicle through the virtual environment. The calibration data may be generated by the same or a different computing device 110 and may be generated from multiple sets of virtual sensor data. Moreover, the virtual sensor data generated during multiple simulations may be aggregated and processed to generate the calibration data. Therefore, the computing device 110 need not immediately output any calibration data after collecting the virtual sensor data. With the calibration data, the real-world vehicle subsystems may be “trained” to identify certain scenarios in accordance with the scenarios simulated in the virtual environment as represented by the virtual sensor data.

Although illustrated as a sedan, the autonomous vehicle 100 may include any passenger or commercial automobile such as a car, a truck, a sport utility vehicle, a crossover vehicle, a van, a minivan, a taxi, a bus, etc. Further, the autonomous vehicle 100 may be configured to operate in a fully autonomous (e.g., driverless) mode or partially autonomous mode.

FIG. 2 illustrates example components of the autonomous vehicle 100. As shown, the autonomous vehicle 100 includes a user interface device 115, a navigation system 120, a communication interface 125, autonomous driving sensors 130, an autonomous mode controller 135, and a processing device 140.

The user interface device 115 may be configured or programmed to present information to a user, such as a driver, during operation of the autonomous vehicle 100. Moreover, the user interface device 115 may be configured or programmed to receive user inputs. Thus, the user interface device 115 may be located in the passenger compartment of the autonomous vehicle 100. In some possible approaches, the user interface device 115 may include a touch-sensitive display screen.

The navigation system 120 may be configured or programmed to determine a position of the autonomous vehicle 100. The navigation system 120 may include a Global Positioning System (GPS) receiver configured or programmed to triangulate the position of the autonomous vehicle 100 relative to satellites or terrestrial based transmitter towers. The navigation system 120, therefore, may be configured or programmed for wireless communication. The navigation system 120 may be further configured or programmed to develop routes from a current location to a selected destination, as well as display a map and present driving directions to the selected destination via, e.g., the user interface device 115. In some instances, the navigation system 120 may develop the route according to a user preference. Examples of user preferences may include maximizing fuel efficiency, reducing travel time, travelling the shortest distance, or the like.

The communication interface 125 may be configured or programmed to facilitate wired and/or wireless communication between the components of the autonomous vehicle 100 and other devices, such as a remote server or even another vehicle when using, e.g., a vehicle-to-vehicle communication protocol. The communication interface 125 may be configured or programmed to receive messages from, and transmit messages to, a cellular provider's tower and the Telematics Service Delivery Network (SDN) associated with the vehicle that, in turn, establishes communication with a user's mobile device such as a cell phone, a tablet computer, a laptop computer, a fob, or any other electronic device configured for wireless communication via a secondary or the same cellular provider. Cellular communication to the telematics transceiver through the SDN may also be initiated from an internet connected device such as a PC, Laptop, Notebook, or WiFi connected phone. The communication interface 125 may also be configured or programmed to communicate directly from the autonomous vehicle 100 to the user's remote device or any other device using any number of communication protocols such as Bluetooth®, Bluetooth® Low Energy, or WiFi. An example of a vehicle-to-vehicle communication protocol may include, e.g., the dedicated short range communication (DSRC) protocol. Accordingly, the communication interface 125 may be configured or programmed to receive messages from and/or transmit messages to a remote server and/or other vehicles.

The autonomous driving sensors 130 may include any number of devices configured or programmed to generate signals that help navigate the autonomous vehicle 100 while the autonomous vehicle 100 is operating in the autonomous (e.g., driverless) mode. Examples of autonomous driving sensors 130 may include a radar sensor, a lidar sensor, a vision sensor, or the like. The autonomous driving sensors 130 help the autonomous vehicle 100 “see” the roadway and the vehicle surroundings and/or negotiate various obstacles while the vehicle is operating in the autonomous mode. In one possible implementation, the autonomous driving sensors 130 may be calibrated in accordance with the virtual driving data output by the computing device 110 as a result of the simulations performed vis-à-vis the virtual environment.

The autonomous mode controller 135 may be configured or programmed to control one or more subsystems 145 while the vehicle is operating in the autonomous mode. Examples of subsystems 145 that may be controlled by the autonomous mode controller 135 may include a brake subsystem, a suspension subsystem, a steering subsystem, and a powertrain subsystem. The autonomous mode controller 135 may control any one or more of these subsystems 145 by outputting signals to control units associated with these subsystems 145. The autonomous mode controller 135 may control the subsystems 145 based, at least in part, on signals generated by the autonomous driving sensors 130. In one possible approach, the autonomous mode controller 135 may be calibrated in accordance with the virtual driving data output by the computing device 110 as a result of the simulations performed vis-à-vis the virtual environment.

The processing device 140 may be programmed to receive and process the virtual data signal generated by the computing device 110. Processing the virtual data signal may include, e.g., generating calibration settings for the autonomous driving sensors 130, the autonomous mode controller 135, or both. The calibration settings may “teach” the autonomous driving sensors 130 and autonomous mode controller 135 to better interpret the environment around the autonomous vehicle 100.

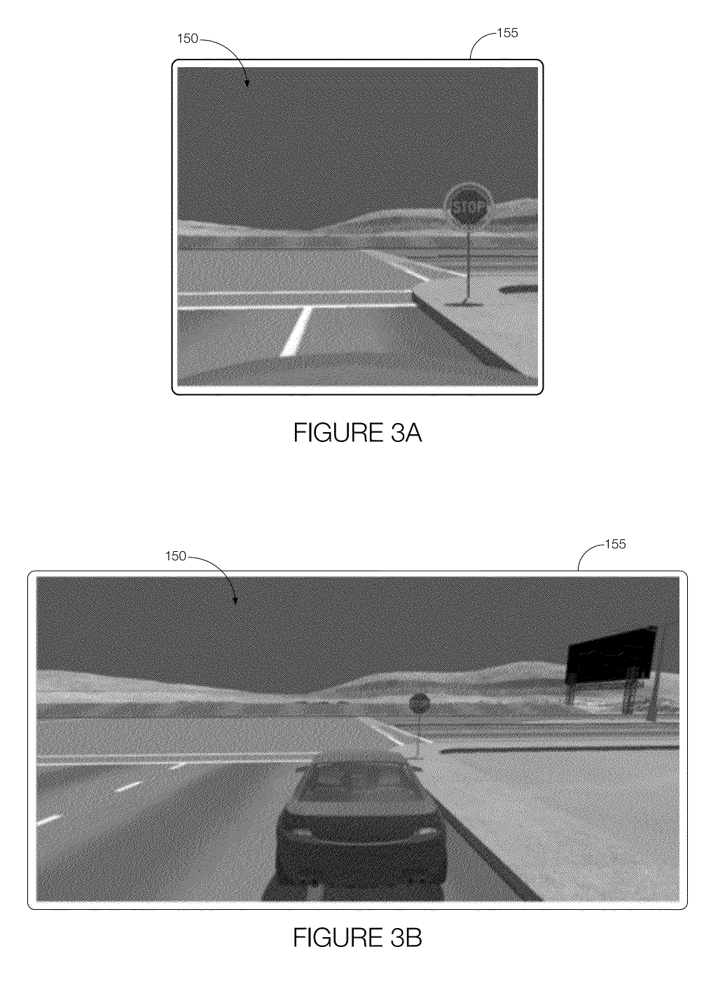

FIGS. 3A-3B illustrates example views of a virtual environment 150 programmed to generate virtual sensor data. FIG. 3A shows a virtual view from an on-board sensor, such as a camera. In other words, FIG. 3A shows how the camera would “see” the virtual environment 150. FIG. 3B, however, shows one possible “experimenter” view. The “experimenter” view allows the camera or other sensor to be positioned outside the virtual vehicle, in the driver's seat of the virtual vehicle, or anywhere else relative to the virtual vehicle.

With the interactive virtual scenarios presented in the virtual environment 150, the user can navigate the virtual vehicle through the virtual environment 150 to test sign and obstacle detection processes, observe autonomous driving process performance, or experiment with switching between autonomous and manual driving modes. The virtual environment 150 may, in real time, present the output of, e.g., the road sign detection classifiers, as shown in FIG. 3A, displaying the location and diameter of each detected sign.

The computing device 110 integrates a virtual driving environment, created using three-dimensional modeling and animation tools, with sensor models to produce the virtual sensor data in large quantities in a relatively short amount of time. Relevant parameters such as lighting and road sign orientation, in the case of sign detection, may be randomized in the recorded data to ensure a diverse dataset with minimal bias.

In one possible implementation, one or more virtual sensors may be positioned within the virtual environment. Each virtual sensor may output virtual sensor data such as camera image data or ray-traced sensor data, depending on the sensor type, to shared memory where it can be accessed and processed in accordance with signal processing code. The data may be processed in a way that reflects the limitations of rear world sensors prior to be output to, e.g., an object detection module. The object detection module may process the simulated sensor data and output information including relative position, size, and object type about any detected objects. Detected objects may be displayed using markings and labels overlaid on a simulation window that shows each sensor's point of view. The output of the computing device may be timestamped and written to a file for later study or use.

Compared to collecting real world data, collecting virtual data is cheaper in terms of time, money, and resources. In just a few minutes, thousands of virtual images of a given road sign type can be received and analyzed. A comparable number of real world data would take hours to collect. Performance of some graphics engines are limited, and the computing device may allow sensor models and signal processing code to interface with high-end graphics engines capable of producing photorealistic camera data with realistic reflections, shadows, textures, and physical irregularities desirable for thorough testing. Additionally, in terms of other sensor types, the computing device may provide access to the full raw data output from the sensors via ray tracing. For example, the virtual lidar sensor may output the full point cloud that a real world lidar sensor may output.

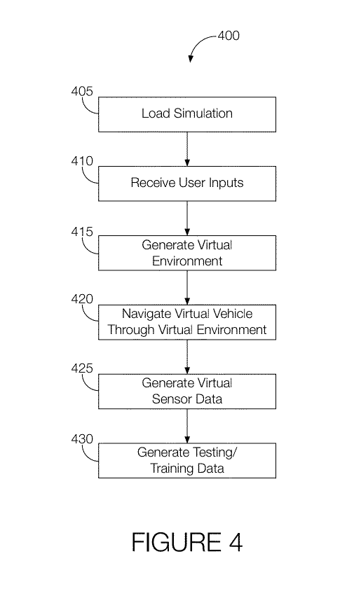

FIG. 4 is a process flow diagram of an example process 400 for testing and/or training one or more autonomous driving sensors 130 according to virtual sensor data collected while navigating the virtual environment.

At block 405, the computing device 110 may load the simulation of the virtual environment. The simulation of the virtual environment may include elements that would be viewable to an autonomous vehicle during real-world operation. For instance, the virtual environment may include virtual roads, trees, signs, traffic control devices (such as stoplights), bridges and other infrastructure devices such as streetlights, other vehicles, pedestrians, buildings, sidewalks, curbs, etc. Moreover, the virtual environment may be programmed to present different roadways and structures. For instance, the different roadways may include an intersection, a highway, a residential street with parked cars, an urban area, a rural area, a freeway, an on-ramp, an exit ramp, a tunnel, a bridge, a dirt or gravel road, roads with different curvatures and road grades, smooth roads, roads with potholes, a road that goes over train tracks, and so on. Further, the virtual environment may simulate different weather and lighting conditions. For instance, the virtual environment may simulate rain, snow, ice, etc., as well as dawn, daytime, evening, dusk, and nighttime lighting conditions.

At block 410, the computing device 110 may receive user inputs that select various testing parameters. The testing parameters may include, e.g., a user input selecting the type of driving conditions. The user input, therefore, may include a selection of the weather conditions, lighting conditions, or both (e.g., rain at dusk) as well as a selection of any other factors including the type of road or area (e.g., intersection, highway, urban area, rural area, etc.).

At block 415, the computing device 110 may generate the virtual environment according to the user inputs received at block 410. The virtual environment may be presented on a display screen 155. The virtual environment may be presented in accordance with the “experimenter” view discussed above or the view from one or more of the autonomous vehicle sensors 130 such as an on-board camera. Moreover, the display screen may present the virtual environment with various conditions selected at block 405, including weather conditions, lighting conditions, or the like.

At block 420, the computing device 110 may navigate the virtual vehicle through the virtual environment. Navigating through the virtual environment may include determining an endpoint via, e.g., a user input and navigating the virtual vehicle through the virtual environment to the endpoint. The autonomous operation of the virtual vehicle may be based on the sensor inputs as if the virtual vehicle were an autonomous vehicle navigating in a real-world environment simulated by the computing device 110. Alternatively, navigating the virtual environment may include displaying the virtual environment as it would appear to one or more autonomous driving sensors 130. So instead of showing the virtual vehicle travelling through the virtual environment or the view of the virtual driver, a user may simply see various views of the autonomous driving sensor 130.

At block 425, the computing device 110 may generate virtual sensor data representing the data collected by the virtual sensors. The virtual sensor data, therefore, may represent the data that would have been collected by real-world autonomous vehicle sensors 130 navigating through a real-world environment identical to that of the simulated environment. For instance, the virtual sensor data may indicate whether the autonomous vehicle sensor 130 would have identified, e.g., a stop sign that is partially hidden, such as partially blocked by a tree, or in low lighting conditions (e.g., at dusk or night with no nearby streetlights). In one possible approach, generating the virtual sensor data includes capturing camera image data or ray-traced sensor data, depending on the sensor type, and storing the captured camera image data or ray-traced sensor data to a memory device where it can be accessed and processed in accordance with signal processing code. The data may be processed in a way that reflects the limitations of rear world sensors prior to being output to, e.g., an object detection module. The object detection module may process the simulated sensor data and output information including relative position, size, and object type about any detected objects. Detected objects may be displayed using markings and labels overlaid on a simulation window (e.g., the display screen 155) that shows each sensor's point of view. The output of the computing device may be timestamped and written to a file for later study or use.

At block 430, the computing device 110 may process the virtual sensor data to generate output data, which may include testing data, teaching data, or both. The output data may be based on the virtual sensor data generated at block 425. That is, output data may help identify particular settings for the autonomous driving sensors 130 to appropriately identify road signs, pedestrians, lane markers, other vehicles, etc., under the circumstances selected at block 410. In some instances, the output data may represent trends in the virtual sensor data including settings associated with identifying the greatest number of objects under the largest set of circumstances. In other instances, the output data may be specific to a set of circumstances, in which case multiple sets of output data may be generated for eventual use in the autonomous vehicle 100. Ultimately, the output data, or an aggregation of output data, may be loaded into the vehicle system 105 as, e.g., calibration data operating in a real-world autonomous vehicle 100. When the calibration data is loaded into the vehicle system 105, the autonomous driving sensors 130 may apply the appropriate settings to properly identify objects under the circumstances selected at block 410.

In general, the computing systems and/or devices described may employ any of a number of computer operating systems, including, but by no means limited to, versions and/or varieties of the Ford Sync® operating system, the Microsoft Windows® operating system, the Unix operating system (e.g., the Solaris® operating system distributed by Oracle Corporation of Redwood Shores, Calif.), the AIX UNIX operating system distributed by International Business Machines of Armonk, New York, the Linux operating system, the Mac OSX and iOS operating systems distributed by Apple Inc. of Cupertino, California, the BlackBerry OS distributed by Blackberry, Ltd. of Waterloo, Canada, and the Android operating system developed by Google, Inc. and the Open Handset Alliance. Examples of computing devices include, without limitation, an on-board vehicle computer, a computer workstation, a server, a desktop, notebook, laptop, or handheld computer, or some other computing system and/or device.

Computing devices generally include computer-executable instructions, where the instructions may be executable by one or more computing devices such as those listed above. Computer-executable instructions may be compiled or interpreted from computer programs created using a variety of programming languages and/or technologies, including, without limitation, and either alone or in combination, Java™, C, C++, Visual Basic, Java Script, Perl, etc. In general, a processor (e.g., a microprocessor) receives instructions, e.g., from a memory, a computer-readable medium, etc., and executes these instructions, thereby performing one or more processes, including one or more of the processes described herein. Such instructions and other data may be stored and transmitted using a variety of computer-readable media.

A computer-readable medium (also referred to as a processor-readable medium) includes any non-transitory (e.g., tangible) medium that participates in providing data (e.g., instructions) that may be read by a computer (e.g., by a processor of a computer). Such a medium may take many forms, including, but not limited to, non-volatile media and volatile media. Non-volatile media may include, for example, optical or magnetic disks and other persistent memory. Volatile media may include, for example, dynamic random access memory (DRAM), which typically constitutes a main memory. Such instructions may be transmitted by one or more transmission media, including coaxial cables, copper wire and fiber optics, including the wires that comprise a system bus coupled to a processor of a computer. Common forms of computer-readable media include, for example, a floppy disk, a flexible disk, hard disk, magnetic tape, any other magnetic medium, a CD-ROM, DVD, any other optical medium, punch cards, paper tape, any other physical medium with patterns of holes, a RAM, a PROM, an EPROM, a FLASH-EEPROM, any other memory chip or cartridge, or any other medium from which a computer can read.

Databases, data repositories or other data stores described herein may include various kinds of mechanisms for storing, accessing, and retrieving various kinds of data, including a hierarchical database, a set of files in a file system, an application database in a proprietary format, a relational database management system (RDBMS), etc. Each such data store is generally included within a computing device employing a computer operating system such as one of those mentioned above, and are accessed via a network in any one or more of a variety of manners. A file system may be accessible from a computer operating system, and may include files stored in various formats. An RDBMS generally employs the Structured Query Language (SQL) in addition to a language for creating, storing, editing, and executing stored procedures, such as the PL/SQL language mentioned above.

In some examples, system elements may be implemented as computer-readable instructions (e.g., software) on one or more computing devices (e.g., servers, personal computers, etc.), stored on computer readable media associated therewith (e.g., disks, memories, etc.). A computer program product may comprise such instructions stored on computer readable media for carrying out the functions described herein.

With regard to the processes, systems, methods, heuristics, etc. described herein, it should be understood that, although the steps of such processes, etc. have been described as occurring according to a certain ordered sequence, such processes could be practiced with the described steps performed in an order other than the order described herein. It further should be understood that certain steps could be performed simultaneously, that other steps could be added, or that certain steps described herein could be omitted. In other words, the descriptions of processes herein are provided for the purpose of illustrating certain embodiments, and should in no way be construed so as to limit the claims.

Accordingly, it is to be understood that the above description is intended to be illustrative and not restrictive. Many embodiments and applications other than the examples provided would be apparent upon reading the above description. The scope should be determined, not with reference to the above description, but should instead be determined with reference to the appended claims, along with the full scope of equivalents to which such claims are entitled. It is anticipated and intended that future developments will occur in the technologies discussed herein, and that the disclosed systems and methods will be incorporated into such future embodiments. In sum, it should be understood that the application is capable of modification and variation.

All terms used in the claims are intended to be given their ordinary meanings as understood by those knowledgeable in the technologies described herein unless an explicit indication to the contrary is made herein. In particular, use of the singular articles such as “a,” “the,” “said,” etc. should be read to recite one or more of the indicated elements unless a claim recites an explicit limitation to the contrary.

The Abstract is provided to allow the reader to quickly ascertain the nature of the technical disclosure. It is submitted with the understanding that it will not be used to interpret or limit the scope or meaning of the claims. In addition, in the foregoing Detailed Description, it can be seen that various features are grouped together in various embodiments for the purpose of streamlining the disclosure. This method of disclosure is not to be interpreted as reflecting an intention that the claimed embodiments require more features than are expressly recited in each claim. Rather, as the following claims reflect, inventive subject matter lies in less than all features of a single disclosed embodiment. Thus the following claims are hereby incorporated into the Detailed Description, with each claim standing on its own as a separately claimed subject matter.

1. A computing device comprising a processing circuit and a data storage medium, wherein the computing device is programmed to:
receive virtual sensor data, wherein the virtual sensor data represents data collected by a virtual sensor associated with autonomously operating a virtual vehicle in a virtual environment;
process the virtual sensor data to identify a limitation of a real-world sensor.

2. The computing device of claim 1, wherein the computing device is programmed to generate the virtual sensor data based at least in part on a virtual navigation of the virtual vehicle through the virtual environment.

3. The computing device of claim 1, wherein the virtual environment includes at least one object detected by the virtual sensor, and wherein the virtual sensor data represents at least one of a relative position, size, and object type associated with the detected object.

4. The computing device of claim 3, wherein the computing device is programmed to identify the detected objected with an overlay displayed on a display screen.

5. The computing device of claim 1, wherein the virtual sensor is based at least in part on at least one autonomous driving sensor incorporated into an autonomous vehicle.

6. The computing device of claim 1, wherein the virtual sensor includes a virtual camera, and wherein the virtual sensor data includes a virtual camera image.

7. The computing device of claim 1, wherein the virtual sensor includes a virtual camera, and wherein the virtual sensor data includes a ray-traced image.

8. The computing device of claim 1, wherein processing the virtual sensor data includes applying a timestamp to the virtual sensor data.

9. A method comprising:
receive virtual sensor data, wherein the virtual sensor data represents data collected by a virtual sensor associated with autonomously operating a virtual vehicle in a virtual environment; and
process the virtual sensor data to identify a limitation of a real-world sensor.

10. The method of claim 9, further comprising generating the virtual sensor data based at least in part on a virtual navigation of the virtual vehicle through the virtual environment.

11. The method of claim 9, wherein the virtual environment includes at least one object detected by the virtual sensor, and wherein the virtual sensor data represents at least one of a relative position, size, and object type associated with the detected object.

12. The method of claim 11, further comprising identifying the detected objected with an overlay displayed on a display screen.

13. The method of claim 9, wherein the virtual sensor is based at least in part on at least one autonomous driving sensor incorporated into an autonomous vehicle.

14. The method of claim 9, wherein the virtual sensor includes a virtual camera, and wherein the virtual sensor data includes a virtual camera image.

15. The method of claim 9, wherein the virtual sensor includes a virtual camera, and wherein the virtual sensor data includes a ray-traced image.

16. The method of claim 9, wherein processing the virtual sensor data includes applying a timestamp to the virtual sensor data.

17. A computing system comprising:
a display screen; and
a computing device having a processing circuit and a data storage medium, wherein the computing device is programmed to:
receive virtual sensor data, wherein the virtual sensor data represents data collected by a virtual sensor associated with autonomously operating a virtual vehicle in a virtual environment; and
process the virtual sensor data to identify a limitation of a real-world sensor.

18. The computing system of claim 17, wherein the virtual environment includes at least one object detected by the virtual sensor, and wherein the virtual sensor data represents at least one of a relative position, size, and object type associated with the detected object.

19. The computing system of claim 18, wherein the computing device is programmed to identify the detected objected with an overlay displayed on the display screen.

20. The computing system of claim 17, wherein the virtual sensor includes a virtual camera, and wherein the virtual sensor data includes at least one of a virtual camera image and a ray-traced image.
